(19) United States
(12) Patent Application Publication
(10) Pub. No.: US 2013/0042465 A1
(43) Pub. Date: Feb. 21, 2013

(54) Process Including Converting Resistive Powder to Fused Heater Element using Laser Metal Deposition Apparatus

(71) Applicants: Brian Esser, Colchester, VT (US); John Knapp, St. Albans, VT (US)

(72) Inventors: Brian Esser, Colchester, VT (US); John Knapp, St. Albans, VT (US)

(73) Assignee: HUSKY INJECTION MOLDING SYSTEMS LTD., Bolton (CA)

(21) Appl. No.: 13/695,297

(22) PCT Filed: Jul. 26, 2011
(86) PCT No.: PCT/US2011/045267

§ 371 Date: Oct. 30, 2012

Related U.S. Application Data
(60) Provisional application No. 61/367,892, filed on Jul. 27, 2010.

(51) Int. Cl. C23C 16/00; C23C 16/56; C23C 16/50

(52) U.S. Cl. 29/611; 427/586

(57) ABSTRACT

A process (200), comprising: a transfer operation (204), including transferring a resistive powder (106) to an electrically insulated element (102); and a converting operating (206), including converting at least some of the resistive powder (106) to a fused heater element (108) by using a laser metal deposition apparatus (110), the fused heater element (108) being fused to the electrically insulated element (102).

### TECHNICAL FIELD

An aspect of the present invention generally relates to (but is not limited to) a process, including (but not limited to): converting a resistive powder to a fused heater element by using a laser metal deposition apparatus.

### BACKGROUND

The first man-made plastic was invented in Britain in 1851 by Alexander PARKES. He publicly demonstrated it at the 1862 International Exhibition in London, calling the material Parkesine. Derived from cellulose, Parkesine could be heated, molded, and retain its shape when cooled. It was, however, expensive to produce, prone to cracking, and highly flammable. In 1868, American inventor John Wesley HYATT developed a plastic material he named Celluloid, improving on PARKES' invention so that it could be processed into finished form. HYATT patented the first injection molding machine in 1872. It worked like a large hypodermic needle, using a plunger to inject plastic through a heated cylinder into a mold. The industry expanded rapidly in the 1940s because World War II created a huge demand for inexpensive, mass-produced products. In 1946, American inventor James Watson HENDRY built the first screw injection machine. This machine also allowed material to be mixed before injection, so that colored or recycled plastic could be added to virgin material and mixed thoroughly before being injected. In the 1970s, HENDRY went on to develop the first gas-assisted injection molding process.

Injection molding machines consist of a material hopper, an injection ram or screw-type plunger, and a heating unit. They are also known as presses, they hold the molds in which the components are shaped. Presses are rated by tonnage, which expresses the amount of clamping force that the machine can exert. This force keeps the mold closed during the injection process. Tonnage can vary from less than five tons to 6000 tons, with the higher figures used in comparatively few manufacturing operations. The total clamp force needed is determined by the projected area of the part being molded. This projected area is multiplied by a clamp force of from two to eight tons for each square inch of the projected areas. As a rule of thumb, four or five tons per square inch can be used for most products.

If the plastic material is very stiff, it will require more injection pressure to fill the mold, thus more clamp tonnage to hold the mold closed. The required force can also be determined by the material used and the size of the part, larger parts require higher clamping force. With Injection Molding, granular plastic is fed by gravity from a hopper into a heated barrel. As the granules are slowly moved forward by a screw-type plunger, the plastic is forced into a heated chamber, where it is melted. As the plunger advances, the melted plastic is forced through a nozzle that rests against the mold, allowing it to enter the mold cavity through a gate and runner system. The mold remains cold so the plastic solidifies almost as soon as the mold is filled. Mold assembly or die are terms used to describe the tooling used to produce plastic parts in molding. The mold assembly is used in mass production where thousands of parts are produced. Molds are typically constructed from hardened steel, etc. Hot-runner systems are used in molding systems, along with mold assemblies, for the manufacture of plastic articles. Usually, hot-runners systems and mold assemblies are treated as tools that may be sold and supplied separately from molding systems.

U.S. Pat. No. 4,897,150 discloses direct write techniques wherein, for example, an electron beam “writes” a pattern in photoresist on an integrated circuit or other semi-conductive element. Some of these prior direct write techniques have also included the use of laser beams. Such laser assisted deposition techniques involve the deposition of metal from an organometallic gas or polysilicon from silane (SiH4).

U.S. Pat. No. 7,001,467 discloses a device and method for depositing a material of interest on a receiving substrate includes a first laser and a second laser, a receiving substrate, and a target substrate. The target substrate comprises a laser transparent support having a back surface and a front surface. The front surface has a coating that comprises the source material, which is a material that can be transformed into the material of interest. The first laser can be positioned in relation to the target substrate so that a laser beam is directed through the back surface of the target substrate and through the laser-transparent support to strike the coating at a defined location with sufficient energy to remove and lift the source material from the surface of the support. The receiving substrate can be positioned in a spaced relation to the target substrate so that the source material is deposited at a defined location on the receiving substrate. The second laser is then positioned to strike the deposited source material to transform the source material into the material of interest.

A conducting silver line was fabricated by using a UV laser beam to first transfer the coating from a target substrate to a receiving substrate and then post-processing the transferred material with a second IR laser beam. The target substrate consisted of a UV grade fused silica disk on which one side was coated with a layer of the material to be transferred. This layer consisted of Ag powder (particle size of a few microns) and a metalloorganic precursor which decomposes into a conducting specie(s) at low temperatures (less than 200° C.). The receiving substrate was a microwave-quality circuit board which has various gold electrode pads that are a few microns thick. A spacer of 25-micron thickness was used to separate the target and receiving substrates.

Silver was first transferred with a focused UV (λ=248 nm or λ=355) laser beam through the target substrate at a focal fluence of 225 mJ/cm2. The spot size at the focus was 40 μm in diameter. A line of “dots” was fabricated between two gold contact pads by translating both the target and receiving substrates together to expose a fresh area of the target substrate for each laser shot while the laser beam remained stationary. The distance between the laser spots was approx. one spot diameter. A pass consisted of approximately 25 dots and a total of 10 passes (superimposed on one another) was made. The target substrate was moved between each pass. After the transfers, the resistance between the gold pads as measured with an ohmmeter was infinite (>20-30 Megaohms).

U.S. Pat. No. 7,014,885 discloses device and method that is useful for creating a deposit of electrically conducting material by depositing a precursor material or a mixture of a precursor material and an inorganic powder that is transformed into an electrical conductor. For creating deposits of metals, such as for conductor lines, any precursors commonly used in chemical vapor deposition (CVD) and laser-induced chemical vapor deposition (LCVD) may be used. Examples include, but are not limited to, metal alkoxides, metal diketonates and metal carboxalates.

U.S. Pat. No. 5,132,248 discloses a process for deposition of material on a substrate, for example, the deposition of metals or dielectrics on a semiconductor laser, the material is deposited by providing a colloidal suspension of the material and directly writing the suspension on the substrate surface by ink jet printing techniques. This procedure minimizes the handling requirements of the substrate during the deposition process and also minimizes the exchange of energy between the material to be deposited and the substrate at the interface. The deposited material is then resolved into a desired pattern, preferably by subjecting the deposit to a laser annealing step. The laser annealing step provides high resolution of the resultant pattern while minimizing the overall thermal load of the substrate and permitting precise control of interface chemistry and inter-diffusion between the substrate and the deposit.

### SUMMARY

The inventors have researched a problem associated with known molding systems that inadvertently manufacture bad-quality molded articles or parts. After much study, the inventors believe they have arrived at an understanding of the problem and its solution, which are stated below, and the inventors believe this understanding is not known to the public.

Current heater construction typically involves packaging of a nichrome wire element (nickel-chromium resistance wire) in various forms. More advanced methods may use screen printed techniques requiring high firing temperatures and/or customized screens for each configuration. Other known methods may rely on thermal spray application of a layer and selectively removing portions of the layer to produce the desired heating element. For example, additional known methods may relay on thermal spray techniques in which a specialized mask is used to create the desired heater configuration and pattern. Still other known methods may utilize inkjet style print heads with the resistive medium suspended in a solvent or other liquid to directly write a patterned heater onto a substrate.

According to one aspect, there is provided a process (200), comprising: a transfer operation (204), including transferring a resistive powder (106) to an electrically insulated element (102); and a converting operating (206), including converting at least some of the resistive powder (106) to a fused heater element (108) by using a laser metal deposition apparatus (110), the fused heater element (108) being fused to the electrically insulated element (102).

Other aspects and features of the non-limiting embodiments will now become apparent to those skilled in the art upon review of the following detailed description of the non-limiting embodiments with the accompanying drawings.

### DETAILED DESCRIPTION OF THE DRAWINGS

The non-limiting embodiments will be more fully appreciated by reference to the following detailed description of the non-limiting embodiments when taken in conjunction with the accompanying drawings, in which:

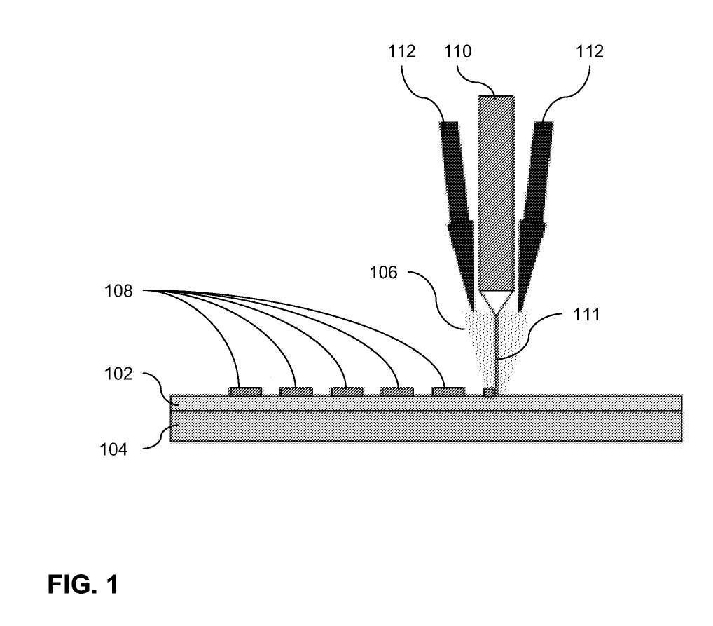

FIG. 1 depicts a schematic representation of a laser metal deposition apparatus (110);

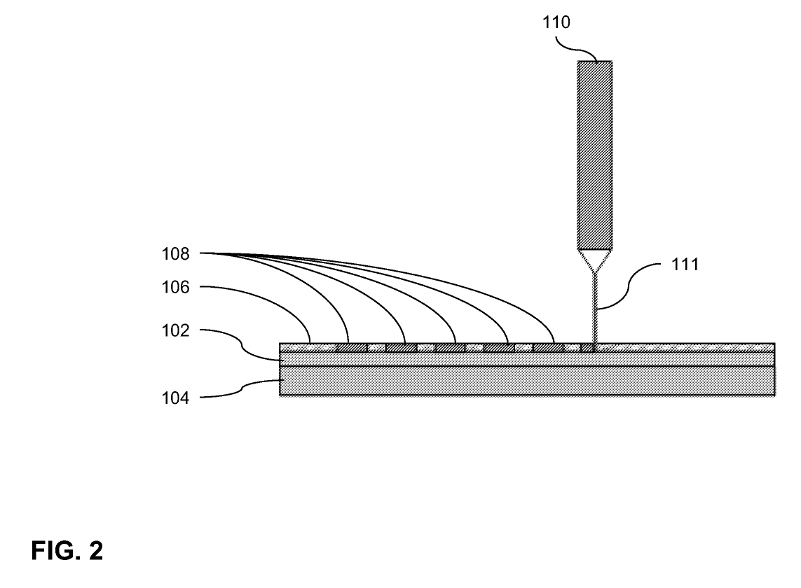

FIG. 2 depicts another schematic representation of the laser metal deposition apparatus (110) of FIG. 1; and

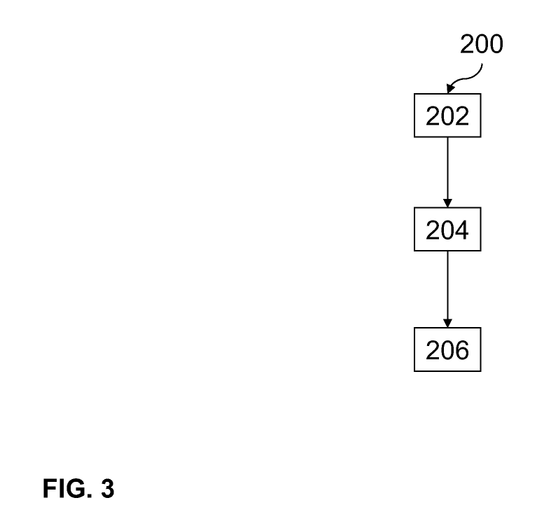

FIG. 3 depicts a schematic representation of a process (200) for using the laser metal deposition apparatus (110) of FIG. 1 or FIG. 2.

The drawings are not necessarily to scale and may be illustrated by phantom lines, diagrammatic representations and fragmentary views. In certain instances, details not necessary for an understanding of the embodiments (and/or details that render other details difficult to perceive) may have been omitted.

### DETAILED DESCRIPTION OF THE NON-LIMITING EMBODIMENT(S)

FIG. 1 depicts the schematic representation of the laser metal deposition apparatus (110). Mold-tool systems, hot-runner systems and molding systems may include, at least in part, components that are known to persons skilled in the art, and these known components will not be described here; these known components may be described, at least in part, in the following reference books (by way of example): (i) “Injection Molding Handbook” authored by OSSWALD/TURNG/GRAMANN (ISBN: 3-446-21669-2), (ii) “Injection Molding Handbook” authored by ROSATO AND ROSATO (ISBN: 0-412-99381-3), (iii) “Injection Molding Systems” 3^{rd} Edition authored by JOHANNABER (ISBN 3-446-17733-7) and/or (iv) “Runner and Gating Design Handbook” authored by BEAUMONT (ISBN 1-446-22672-9). It will be appreciated that for the purposes of this document, the phrase “includes (but is not limited to)” is equivalent to the word “comprising”. The word “comprising” is a transitional phrase or word that links the preamble of a patent claim to the specific elements set forth in the claim which define what the invention itself actually is. The transitional phrase acts as a limitation on the claim, indicating whether a similar device, method, or composition infringes the patent if the accused device (etc) contains more or fewer elements than the claim in the patent. The word “comprising” is to be treated as an open transition, which is the broadest form of transition, as it does not limit the preamble to whatever elements are identified in the claim.

An electrically insulated element (102) is placed on a substrate (104). A resistive powder (106) is placed on the electrically insulated element (102). At least some of the resistive powder (106) is converted to a fused heater element (108) by using a laser metal deposition apparatus (110). The fused heater element (108) becomes fused to the electrically insulated element (102). The electrically insulated element (102) may include a layer of insulation material. The substrate (104) may include, for example, a layer of substrate material.

Examples of the electrically insulated element (102) may include: aluminum nitride, aluminum oxide, magnesium oxide, zirconia, mica, diamond, etc. Example of the substrate (104) may include: carbon steel, tool steel, stainless steel, copper and copper based alloys, aluminum, titanium, aluminum nitride, aluminum oxide, silicon carbide, or other metallic or ceramic materials. Example of the resistive powder (106) may include: nickel-chromium (also known as ni-chrome), conductive ceramics, tungsten, etc.

According to a first variation, the placing of the resistive powder (106) on the electrically insulated element (102) includes (but is not limited to): using a feeder nozzle (112) to spray the resistive powder (106) on the electrically insulated element (102).

FIG. 2 depicts another schematic representation of the laser metal deposition apparatus (110) of FIG. 1. According to a second variation, the placing of the resistive powder (106) on the electrically insulated element (102) includes (but is not limited to): depositing the resistive powder (106) as a layer on the electrically insulated element (102).

FIG. 3 depicts a schematic representation of the process (200) for using the laser metal deposition apparatus (110) of FIG. 1 or FIG. 2. The process (200) includes (but is not limited to): (i) a fixing operation (202); (ii) a transfer operation (204); and (iii) a converting operating (206). The fixing operation (202) includes (but is not limited to): fixing the electrically insulated element (102) on a substrate (104). The transfer operation (204) includes (but is not limited to): transferring a resistive powder (106) to the electrically insulated element (102). The converting operating (206) includes (but is not limited to): converting at least some of the resistive powder (106) to a fused heater element (108) by using a laser metal deposition apparatus (110). The fused heater element (108) then becomes fused to the electrically insulated element (102).

It will be appreciated that the laser metal deposition apparatus (110) may be used to create or to form a customized heater profile (wattage and watt distribution) in a single write step. By directly writing the heater element, that is, using the converting operating (206), the cost may be reduced and the number of steps required to produce the fused heater element (108) are also reduced. In addition, the ability to articulate a laser head of the laser metal deposition apparatus (110) may allow a build up of the fused heater element (108) on a contoured surface, and/or a complex-shaped surface.

The laser metal deposition apparatus (110) uses a laser energy source to fuse the resistive powder (106) on the electrically insulated element (102), such as a ceramic including magnesium oxide or aluminum oxide, as well as diamond based materials. Several method may be used to position the resistive powder (106) on the over the electrically insulated element (102). The resistive powder (106) may be: (i) fed into a laser beam using a compressed gas (as depicted in FIG. 1), or (ii) may be spread over a surface to a prescribed thickness and selectively fused to the substrate (104) using the laser beam path to determine the element configuration (as depicted in FIG. 2). Additional passes of a laser beam may be used to make thicker layers as desired for increased flexibility in controlling the thermal and electrical characteristics of the fused heater element (108). A laser head may move (or be steered via mirrors), the substrate (104) may be moved, or even both may be moved to achieve a desired geometry and configuration for the fused heater element (108).

An aspect (or example) of the present invention provide a process for producing a profiled heating element in a single step on a substrate (104) using a laser metal deposition (LMD), in which a powder is fed into a laser beam focused on the surface of a substrate (104). The powder is fused to the substrate (104) by the localized laser energy in only the regions in which the laser beam is focused. By applying a trace of the correct material to directly form the heater element trace, a customized heater may be built upon the substrate (104) (such as a ceramic material, an insulated substrate, etc.) in one direct writing step with no requirements for either masking or selective removal of the deposited material. This arrangement allows for the creating of a customized heater element with lower cost and less steps than would otherwise be the case using known methods.

It is understood that the scope of the present invention is limited to the scope provided by the independent claims, and it is also understood that the scope of the present invention is not limited to: (i) the dependent claims, (ii) the detailed description of the non-limiting embodiments, (iii) the summary, (iv) the abstract, and/or (v) description provided outside of this document (that is, outside of the instant application as filed, as prosecuted, and/or as granted). It is understood, for the purposes of this document, the phrase “includes (but is not limited to)” is equivalent to the word “comprising”. The word “comprising” is a transitional phrase or word that links the preamble of a patent claim to the specific elements set forth in the claim which define what the invention itself actually is. The transitional phrase acts as a limitation on the claim, indicating whether a similar device, method, or composition infringes the patent if the accused device (etc) contains more or fewer elements than the claim in the patent. The word “comprising” is to be treated as an open transition, which is the broadest form of transition, as it does not limit the preamble to whatever elements are identified in the claim. It is noted that the foregoing has outlined the non-limiting embodiments. Thus, although the description is made for particular non-limiting embodiments, the scope of the present invention is suitable and applicable to other arrangements and applications. Modifications to the non-limiting embodiments can be effected without departing from the scope of the independent claims. It is understood that the non-limiting embodiments are merely illustrative.

What is claimed is:

1. A process (200), comprising:
a transfer operation (204), including transferring a resistive powder (106) to an electrically insulated element (102); and
a converting operating (206), including converting at least some of the resistive powder (106) to a fused heater element (108) by using a laser metal deposition apparatus (110), the fused heater element (108) being fused to the electrically insulated element (102).

2. The process (200) of claim 1, further comprising:
a fixing operation (202), including fixing the electrically insulated element (102) on a substrate (104).

3. The process (200) of claim 1, wherein:
the transfer operation (204) further includes:
using a feeder nozzle (112) to spray the resistive powder (106) on the electrically insulated element (102).

4. The process (200) of claim 1, wherein:
the transfer operation (204) further includes:
depositing the resistive powder (106) as a layer on the electrically insulated element (102).
